(19) United States
(12) Patent Application Publication
(10) Pub. No.: US 2006/0227639 A1
(43) Pub. Date: Oct. 12, 2006

(54) Current sensing circuit and method of operation

(76) Inventors: Rico Srowik, Dresden (DE); Marco Goetz, Radebeul (DE); Giacomo Curatolo, Dresden (DE)

Correspondence Address: SLATER & MATSIL LLP, 17950 PRESTON ROAD, SUITE 1000, DALLAS, TX, 75252, US

(21) Appl. No.: 11/094,812

(22) Filed: Mar. 30, 2005

(51) Int. Cl. G11C 7/02

(52) U.S. Cl. 365/207

(57) ABSTRACT

A method for sensing current conducted through a memory cell in which a memory cell current is supplied to, or drawn from, a first sensing node. The first sensing node is defined by a common connection point between the first terminal of a sensor element and an input of an inverting amplifier. A second sensing node is defined by a common connection point between a second terminal of the sensor element and the output of the inverting amplifier. The method further includes applying a reference potential to a reference input of the inverting amplifier, wherein the inverting amplifier is operable to apply substantially the reference potential to the first sensing node and to produce, in response, a sensor signal at the second sensing node, the sensor signal representative of the memory cell current supplied to, or drawn from, the first sensing node. Subsequently, the sensor signal is detected, and accordingly, the memory cell current supplied to, or drawn from the first sensing node can be ascertained.

### TECHNICAL FIELD

The present invention relates to current sensing circuits and methods, and more particularly to a system and method for sensing current conducted through memory cells.

### BACKGROUND

FIG. 1 illustrates a typical system used to sense current conducted through a memory cell as known in the art. The system includes a memory cell 108 whose conduction current is to be determined, a detection element 112 (typically a capacitor), and a sense amplifier 120. During a read operation, memory cell 108 is selected, biasing conditions are applied to the selected memory cell 108, and a test is conducted to determine if the memory cell 108 is operable in a conductive state. The applied biasing conditions typically include raising a first bitline BL coupled to the memory cell drain terminal to a supply voltage, lowering a second bitline/BL coupled to the source of the memory cell to ground voltage, and applying a predetermined voltage to the memory cell gate terminal via a wordline WL. The applied gate voltage will render the memory cell 108 conductive when the applied voltage meets or exceeds the threshold voltage of the memory cell. Typically, a relatively high threshold voltage is needed to render a programmed memory cell (a cell that stores a logical “0”), and a relatively low threshold voltage is required to render an erased memory cell (a cell storing a logical “1”) conductive. Accordingly, by knowing at what threshold voltage a memory cell conducts, the content of the memory cell can be determined.

Detection of the memory cell's conduction state is made in the conventional system using a detector 112 and a sense amplifier 120. When the applied gate voltage meets or exceeds the threshold voltage of the memory cell, the cell conducts a cell current I_{cell} output from the source terminal toward ground potential. For erased and programmed memory cells having the same applied gate voltage, the conduction current will be higher for the memory cell in an erased state compared to the current conducted from the memory cell in a programmed state.

The current is supplied to a detector circuit 112, which is often implemented as a capacitor, and the current supplied thereto to charge the capacitor to a particular voltage V_{detect}, which may range from 200-400 mV. This voltage is subsequently supplied to a sense amplifier, which compares the V_{detect} to a reference voltage V_{R} to determine if the memory cell exhibits a conduction state. For example, if V_{detect}>V_{R} then a conduction state is deemed detected. Alternatively, if V_{R}>V_{detect}, then a non-conduction state is sensed.

Although generally effective, the conventional current sensing circuit and method suffers from disadvantages resulting from the generation of the detection voltage V_{detect} at the source terminal of the selected memory cell. One problem accompanying this condition is the phenomenon of the “side” or “neighbor leakage effect.” In particular, the charging of the detector capacitor 112 creates a voltage on bitline/BL, which is coupled to the drain terminal of neighboring memory cell 108. This voltage creates a leakage current I_{leakage} through the neighboring cell 109, as the neighboring cell 109 receives the same applied gate voltage as the selected memory cell 108, and the source terminal of the neighboring cell 109 is discharged to ground potential when not selected. The possibility of inadvertently biasing the neighboring cell 109 into conduction is further increased if the detection voltage V_{detect} is raised, which is desired in order to sense the detected voltage more reliably.

A second problem associated with the generation of the V_{detect} voltage on the source terminal of the tested memory device is the increase in the overhead supply voltage required. Specifically, the presence of the V_{detect} voltage on the source terminal will require that the supply voltage applied to the drain terminal of the memory cell be raised by an equal amount in order to provide the intended drain-source forward voltage. The required increase in the overhead supply voltage is particularly burdensome in power limited applications such as battery-power Flash EEPROM memories, where higher supply voltages cannot be maintained.

What is therefore needed is an improved memory device architecture and corresponding method for sensing memory cell current therein.

### SUMMARY OF THE INVENTION

The present invention provides an improved current sensing circuit and method of operation, whereby the current input to or output from a memory cell is detected using without the application of a significant offset voltage on the memory cell. The invention permits the use of larger detection signals to more reliably detect conduction and non-conduction memory cell states without the aforementioned neighbor leakage effect, or higher power supply voltages.

In an exemplary embodiment of the invention, a method for sensing memory cell current is presented in which memory cell current is supplied to, or sunk from, a first sensing node. The first sensing node is defined by a common connection point between the first terminal of a sensor element and an input of an inverting amplifier. A second sensing node is defined by a common connection point between a second terminal of the sensor element and the output of the inverting amplifier. The method further includes applying a reference potential to a reference input of the inverting amplifier, wherein the inverting amplifier is operable to apply substantially the reference potential to the first sensing node and to produce, in response, a sensor signal at the second sensing node, the sensor signal representative of the current supplied to, or sunk from, the first sensing node.

These and other features of the invention will be better understood when taken in view of the following drawings and detailed description.

### BRIEF DESCRIPTION OF THE DRAWINGS

FIG. 1 illustrates a conventional memory device for sensing memory cell current as known in the art.

FIG. 2A illustrates a method for sensing memory cell current in accordance with one embodiment the present invention;

FIG. 2B illustrates a first embodiment of a current sensing circuit in accordance with the present invention;

FIG. 2C illustrates a second embodiment of a current sensing circuit in accordance with the present invention;

FIG. 3A illustrates an exemplary embodiment of the first current sensing circuit shown in FIG. 2B in accordance with the present invention;

FIG. 3B illustrates an exemplary embodiment of the second current sensing circuit shown in FIG. 2C in accordance with the present invention;

FIG. 4A illustrates a first detailed embodiment of the current sensing circuit shown in FIG. 3A in accordance with one embodiment of the present invention;

FIG. 4B illustrates a second detailed embodiment of the current sensing circuit shown in FIG. 3A in accordance with one embodiment of the present invention;

FIG. 4C illustrates a third detailed embodiment of the current sensing circuit shown in FIG. 3A in accordance with one embodiment of the present invention; and

FIG. 4D illustrates a graph showing the sensor signal response of the current sensing circuit shown in FIG. 4C in accordance with the present invention;

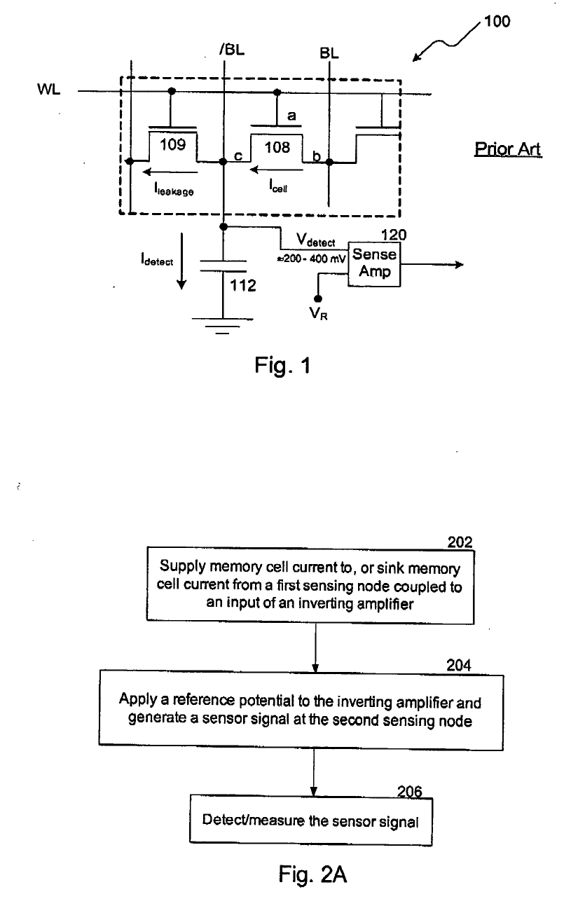

For clarity, previously defined features retain their reference numerals in subsequent drawings.

### DETAILED DESCRIPTION OF ILLUSTRATIVE EMBODIMENTS

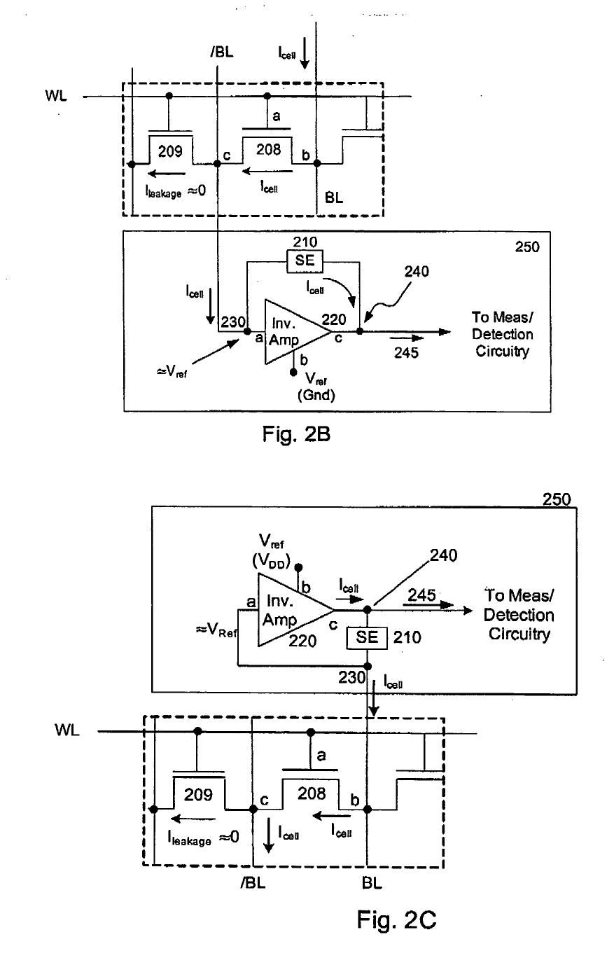

FIG. 2A illustrates a method for sensing memory cell current in accordance with an embodiment of the present invention. The operation begins at 202, whereby memory cell current is supplied to, or drawn from a first sensing node. As will be further described below, the first sensing node may be coupled to either the input of the memory cell, for example, the drain terminal of a memory cell FET, or an output terminal of the memory cell, such as the source terminal of a memory cell FET. Each of these embodiments is described and illustrated below. A second terminal of the sensor element and an output port of the inverting amplifier are coupled together to form a second sensing node.

At 204, the method further includes applying a reference potential to a reference input of the inverting amplifier. In an exemplary embodiment in which the current sensing circuit is coupled to the drain terminal of a memory cell FET, the applied reference potential is the power supply voltage V_{DD}. In a second exemplary embodiment in which the current sensing circuit is coupled to the source terminal of a memory cell FET, the reference potential applied is ground potential. The reference input of the inverting amplifier may be internal to the inverting amplifier. In another exemplary embodiment, the inverting amplifier comprises an operational amplifier, the non-inverting input of which serves as the reference input. Each of these embodiments is illustrated below.

The inverting amplifier is operable to apply substantially the reference potential to the first sensing node. The application of substantially the reference potential at the first sensing node, and the flow of memory cell current I_{cell} moving into or out of the first sensing node produces a voltage and current across the sensor element, the magnitude of which is proportional to the memory cell current I_{cell}. Accordingly, a sensor signal 245 is produced at the second sensing node, the sensor signal being representative of the memory cell current I_{cell}.

At 206, the sensor signal 245 is detected or measured, and accordingly the memory cell current I_{cell} can be sensed and/or quantitatively measured. Detection/measurement may be accomplished by a variety of means. In one embodiment a comparator circuit (e.g., a sense amplifier) is used, whereby the sensor signal is compared to a predefined reference signal to determine the presence of memory cell conduction and/or the magnitude of the memory cell current I_{cell} conducted. Of course, other detection methodologies may be employed using the present invention as well.

FIG. 2B illustrates a first embodiment of a current sensing circuit 250 in accordance with the present invention, with previously-identified features retaining their reference numerals. The current sensing circuit 250 includes a sensor element 210, inverting amplifier 220, a first sensing node 230, and a second sensing node 240. In this embodiment, the first sensing node 230 is coupled to the source terminal of the memory cell FET 208 for receiving substantially cell current I_{cell} therefrom. Imperfections in the operation of the inverting amplifier may lead to the conduction of leakage current I_{leakage} within neighboring memory cell 209, although this current will be minimal compared to the magnitude of I_{cell}. In such instances, the magnitude of I_{cell} supplied to the first sensing node 230 may be a predefined offset of I_{cell}. The current sensing circuit 250 may be integrated with the memory cell 208, or comprise a separate circuit, which is externally coupled thereto. Memory cell 208 is illustrated as a single bit memory cell, although those skilled in the art will appreciate that the present invention is equally applicable to multi-bit memory cells. Further specifically, the memory cell 208 may be any non-volatile memory structure such as those employed in NROM or floating gate devices, or a memory cell structure within a volatile memory device. Still further, the control input of the memory cell may comprise a photosensitive junction the state of which can be controlled by means of an optical signal. Further exemplary, the conduction state of the memory cell may be controlled via phasing the control signal in a particular manner, as known in the art. Those skilled in the art will appreciate that a host of different signal modalities and techniques may be used to control the flow of current within a memory cell, each of which may be employed in the present invention.

The sensor element 210, in a particular embodiment, comprises a two terminal, passive element, such as a capacitor, inductor, or resistor, or a combination of these components. The inverting amplifier 220 is operable to set the potential of the inverting input 220a to substantially the potential applied to the reference input 220b. In a particular embodiment, the inverting amplifier 220 is an operational amplifier in which the inverting input is used as 220a, the non-inverting input is used as the reference input 220b, and the operational amplifier output functions as the output 220c. In another embodiment, the inverting amplifier 220 is a transconductance amplifier similarly configured to the afore-described operational amplifier. These and other embodiments of the inverting amplifier 220 are further described and illustrated below.

The sensor element 210 is coupled in parallel with the inverting amplifier 220, whereby a first terminal of the sensor element 210 and the inverting input of the inverting amplifier 220 are coupled together to define a first sensing node 230. Similarly, the second terminal of the sensor element 210 and the output terminal 220c of the inverting amplifier 220 are coupled together to define a second sensing node 240 at which a sensor signal (which may be provided in voltage or current, analog or digital form) 245 is produced. The reference input 220b of the inverting amplifier 220 (which may be internal to the inverting amplifier) is coupled to receive a reference potential. The operation of the inverting amplifier 220 provides a potential at the first sensing node 230, which is substantially the reference potential applied at the second input 220b. Memory cell current I_{cell} is conducted to the second sensing node 240, producing a sensor signal 245. As the sensor signal 245 is representative of the memory cell current I_{cell}, detection and/or measurement of the memory cell current can be ascertained. In the foregoing embodiment, the memory cell current applied to node 240 constitutes the memory cell current I_{cell} output from the memory cell 208. In other embodiments however, the memory cell current applied to node 240 may be include a predefined current offset (+ or −) depending upon whether the circuitry connecting to node 230 sinks or sources current. In such an embodiment, the resultant current applied to node 240 is still representative of the memory cell current, and accordingly the sensor signal 245 developed at node 240 remains representative of the memory cell current I_{cell} output from the memory cell 208.

FIG. 2C illustrates a second embodiment of a current sensing circuit in accordance with the present invention, with previously defined features retaining their original reference numerals. In this embodiment, the current sensing circuit 250 is coupled to an input port of the memory cell, which is illustrated as the drain terminal of the memory cell FET 208. As noted above, the current sensing circuit 250 may be integrated with the memory cell 208, or comprise a separate circuit that is externally coupled to the memory cell 208.

As shown, V_{ref} (in one embodiment, V_{DD}, the supply memory cell voltage) is supplied to the reference input 220b, and responsive thereto, the inverting amplifier 220 applies substantially V_{ref} at the first sensing node 230. Memory current I_{cell is} additionally output to the second sensing node 240. In one embodiment the memory cell current I_{cell} includes a predefined amount of offset current (+ or −), depending upon whether the connecting circuitry sinks and/or supplies current to the second sensing node 240.

Memory cell current I_{cell} (possibly plus a small amount of leakage current I_{leakage} drawn by neighboring cell 209) is sunk from the first sensing node 230 into the memory cell 208. The sensor signal developed at node 240 (which can be either a voltage or current, analog or digital formatted signal) is subsequently sensed, detected or measured using such circuitry as a sense amplifier or other type of comparator circuitry. These and other detection embodiments are further illustrated and described below.

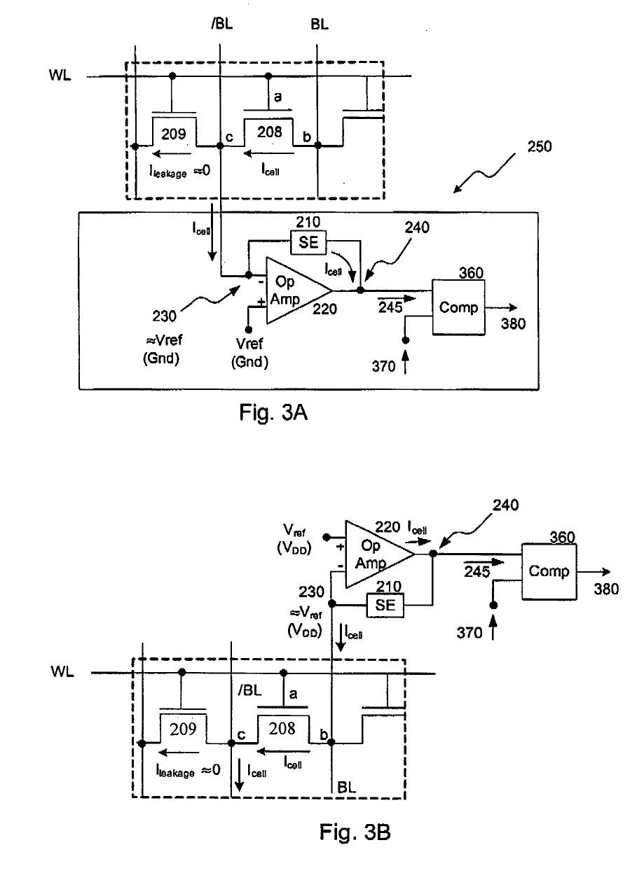

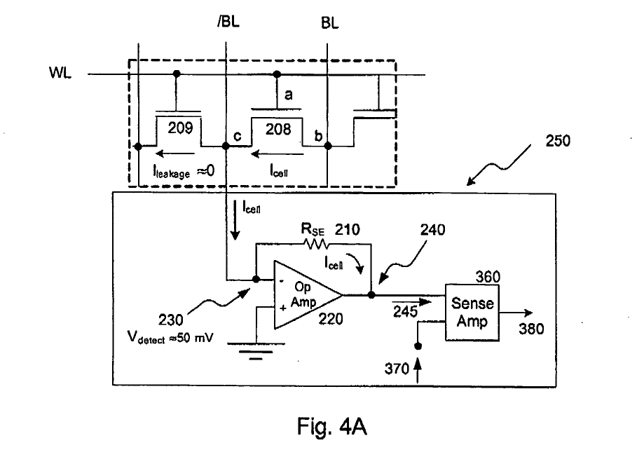

FIG. 3A illustrates an exemplary embodiment of the current sensing circuit shown in FIG. 2A in accordance with the present invention, with previously described features retaining their reference numerals. As shown, an operational amplifier is employed as the inverting amplifier 220, whereby memory cell current I_{cell} (possibly minus a small amount of leakage current I_{leakage} drawn by neighboring cell 209) is supplied from the memory cell FET source terminal to the inverting input of the operational amplifier. A first terminal of sensor element 210 is coupled to the inverting input of the operational amplifier 220, forming the first sensing node 230. A second terminal of the sensor element 210 and the output of the operational amplifier 220 are coupled together to form the second sensing node 240. The non-inverting input of the operational amplifier 220 is coupled to receive the reference potential, which is selected at ground potential in this embodiment. The current sensing circuit 250 further includes a comparator 360 coupled to receive the sensor signal 245 and a reference signal 370. In a particular embodiment, the comparator 360 is a sense amplifier operable to compare the sensor signal 245 to a predefined reference signal which, in a particular embodiment, is a sensor signal originating from a reference memory cell corresponding to memory cell 208. In a specific embodiment, the output signal 380 consists of a first output signal (e.g., a logical 0) if the sensor signal 245 exceeds the reference signal 370, or a second output signal (e.g., a logical 1) if the sensor signal 245 does not exceed the reference signal 370.

FIG. 3B illustrates an exemplary embodiment of the current sensing circuit shown in FIG. 2B in accordance with the present invention. Previously-described features are indicated using original reference numbers.

The inverting amplifier 220 is implemented as an operational amplifier having an inverting input coupled to the drain terminal of the memory cell 208b and to first sensing node 230 from which memory cell current I_{cell} (possibly plus a small amount of leakage current I_{leakage} drawn by neighboring cell 209) is drawn. The non-inverting input is coupled to receive a reference potential, power supply voltage V_{DD} in the illustrated embodiment. Sensor element 210 is coupled between the first and second sensing nodes 230 and 240. Memory cell current I_{cell} is further output to the second sensing node 240. In a particular embodiment, memory cell current I_{cell} supplied to second sensing node 240 includes a predefined amount of current (±), depending upon whether current is drawn from or supplied to the operational amplifier and/or comparator circuitry 360 coupled to the second sensing node 240, or to the operational amplifier 220 input at the first sensing node 230. Notwithstanding the predefined current offset, the current supplied to the second sensing node 240 remains representative of the memory cell current supplied to the memory cell 208.

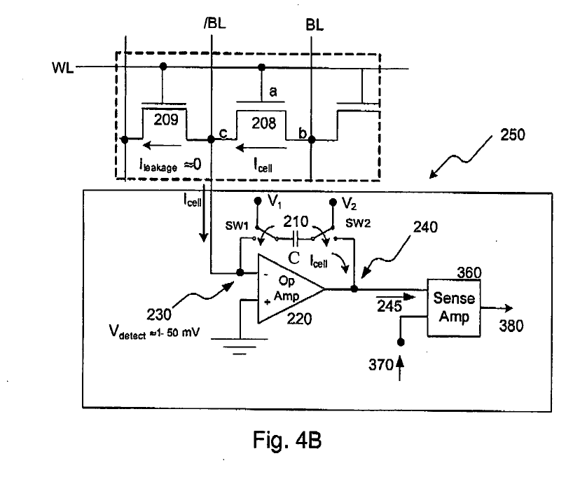

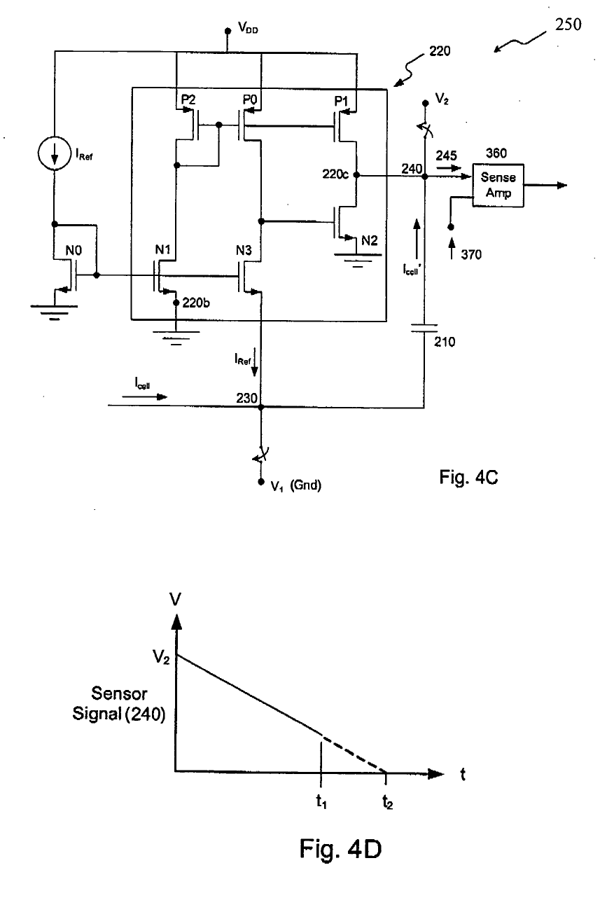

FIG. 4A illustrates a first detailed embodiment of the current sensing circuit 250 shown in FIG. 3A in which the sensor element 210 constitutes a resistor. The resistor may be of any particular construction; for example it may be formed of resist material typically used in semiconductor manufacturing processes when the current sensing circuit is monolithically formed with the memory cell. Alternatively, the resistor may be a discretely formed apart from other components of the circuit 250. The resistance value of the resistor will vary depending upon the desired operating conditions, and may, for example, range between 10 k (×10³) ohms and 1 M (×10⁶) ohms, a particular example being 100 k ohms.

During a current sensing operation in which the state of the device 208 is ascertained, the voltages along the wordline and bitline are raised, thereby activating the gate 208a and drain 208b terminals of the memory cell FET. The voltage of the source terminal 208c is set substantially to 0V by applying a ground potential to the non-inverting input of the operational amplifier 220. This voltage is substantially mirrored to the first sensing node 230 to which the source terminal 208c is coupled. Non-ideal conditions of the operational amplifier create some offset from the applied reference potential coupled to the non-inverting input of the operational amplifier 220, and in a particular embodiment when the applied reference potential is ground potential, the virtual voltage applied to the first sensing node 230 is approximately between 1-50 mV. Such a voltage error may be sufficient to render neighboring memory cell 209 slightly conductive to permit the flow of leakage current I_{leakage} therethrough, although such current will be substantially less than the intended memory cell current I_{cell} supplied to the first sensing node 230.

In a specific embodiment in which the applied gate voltage is sufficient to forward bias the memory cell 208 into conduction, current is conducted from the drain terminal 208b and output from the source terminal 208c to the first sensing node 230, for example 10 uA. In such an instance, the 10 uA current is conducted through the 100 kΩ resistor 210, developing a 1V voltage drop in the illustrated example.

Accordingly, the sensor signal 245 reaches a level of −1V, which when compared to the reference signal 370 (established, for example, at −0.5 V), indicates a conductive state of the memory cell 208. The sense amplifier 360 subsequently outputs an output signal 380, indicating a conductive state for the memory cell. Additionally, if the magnitude of the applied gate voltage is known (as is usually the case), the storage state of the memory cell can be obtained. As an example, if the applied gate voltage is above, e.g., 3 V and conduction does not occur, then it can be concluded that the cell is in a programmed state, as a higher threshold voltage is needed to render the cell conductive. Alternatively, if the applied gate voltage is lower, e.g., 2 V, and the cell becomes conductive, then it can be determined that the cell is in an erased state, as a lower threshold voltage is sufficient to activate the cell in this condition.

Alternatively, if the supplied gate voltage does not meet or exceed the cell's threshold voltage (e.g. when a relatively low gate voltage is supplied to a programmed cell), no current is supplied to the first sensing node 230, and the sensor signal 245 is substantially the reference potential applied to the operational amplifier 220, 1-50 mV in the illustrated example. The sense amplifier 360 compares the sensor signal 245 (e.g., 0V) with the reference signal 370 (e.g., −0.5 V), and accordingly produces an output signal 380 representing a non-conductive state of the memory cell. Those skilled in the art will appreciate that the foregoing resistor, current and voltage values are exemplary, and may be modified (either higher or lower) to meet design requirements.

In another embodiment of a read operation, a predefined gate voltage is applied to each memory cell, and the memory cell's current I_{cell} (e.g., 10 uA) subsequently output. In such an arrangement, memory cells that have a lower threshold voltage output higher memory cell current, compared to memory cells having a higher threshold voltage. The detection circuitry is operable to measure the output memory cell current I_{cell}, and accordingly determine the state of the memory cell.

FIG. 4B illustrates a second detailed embodiment of the current sensing circuit shown in FIG. 3A in accordance with one embodiment of the present invention. As shown, the sensor element 210 includes a capacitor C and switches SW1 and SW2. When switches SW1 and SW2 are coupled to the operational amplifier 220, the capacitor C is operable to charge responsive to receiving the memory cell current I_{cell} supplied to the first sensing node 230. Accordingly, the sensor signal 245 varies as a function of the current supplied to the first sensing node 230, with the voltage at the first sensing node 230 remaining substantially fixed at or near ground potential. Switches SW1 and SW2 are additionally operable to switch to a predefined voltage in order to charge the capacitor C to a predefined voltage. In an exemplary embodiment, the capacitor is chargeable to V_{DD}, and the ranges between 10 to 1000 fF (×10⁻¹⁵ Farads), and in a particular embodiment is 100 fF.

FIG. 4C illustrates a third detailed embodiment of the current sensing circuit 250 shown in FIG. 3A in accordance with one embodiment of the present invention. As shown, the operational amplifier 220 includes PMOS transistors P0-P2 and NMOS transistors N0-N3 connected as shown. A current source provides a reference current to the drain terminal of N0. Gate terminals of N1 and N3 are controlled to draw current proportional to the reference current I_{Ref}. Source terminals of N3 and N1 define the inverting and non-inverting terminals, respectively, of the operational amplifier. P1 and N2 form pull-up and pull-down transistors, respectively, for the output of the operational amplifier 220.

During operation, capacitor C is initially charged by controlling switches to couple to voltage sources V₁ (Gnd) and V₂ (V_{DD}). Subsequently, switches are controlled to disconnect from their respective voltage sources. Thereafter, current I_{cell} is supplied from the memory cell to the first sensing node 230, as described previously. The source terminal of N1, representing the non-inverting input of the operational amplifier is tied to ground. Consequently, the source of N3 is also substantially tied to ground and supplies the reference current I_{Ref} to the first sensing node 230. These currents sum and are supplied to the capacitor C. Accordingly, the current supplied to capacitor C is offset from the memory cell current I_{cell} by the predetermined current I_{ref}, although the supplied current remains representative of the memory cell current I_{cell}.

As the drain terminal of N2 is initially held high by pre-charged capacitor C, N2 becomes conductive and discharges capacitor C at a rate determined substantially by the memory cell current I_{cell} in an exemplary case in which I_{cell}>I_{ref}. The sensor voltage 245 continues integrating down until the capacitor is completely discharged. In a specific implementation, memory cell current I_{cell} is 25 uA, reference current I_{Ref} is 15 uA, capacitor C is 100 fF, and the gate periphery ratios of transistors N0, N1, and N3 is 1, transistor N2 is 2 or 4, and transistors P0-P2 is 4. Voltage offset at node 230 is 1-2 mV above ground potential. Those skilled in the art will appreciate that different current, capacitance, and gate periphery ratios may be chosen under alternative embodiments of the present invention.

FIG. 4D illustrates the sensor signal 245 versus time of the current sensing circuit shown in FIG. 4C. The sensor signal 245 is the sensor voltage present at the second sensing node 240, to representing the time at which voltage sources V₁ and V₂ are disconnected from capacitor C and memory cell current is supplied to capacitor C, and t₁ representing the time at which detection/measurement of the sensor signal 245 occurs. The sensor signal 245 decreases from V₂ at a rate substantially determined by I_{cell}, the memory cell current I_{cell} determinable from the time rate of change of the voltage at the second sensing node 240.

As shown, detection/measurement of the sensor signal 245 can take place at a predetermined time t₁, or alternatively at a time t₂, at, or after which time the sensor signal 245 is expected to have completely discharged if a predefined minimum level of memory cell current I_{cell} is output. In such an embodiment, detection or measurement of a sensor voltage higher than ground potential (or a predefined amount above ground) would indicate that less than the predefined minimum level of memory cell current is being supplied by the memory cell, i.e., that the memory cell is not in a conduction state.

As can be seen from the exemplary embodiments, current sensing of the memory device can be achieved by detecting varying voltage/current conditions at the second sensing node 240 while maintaining a constant, predefined potential (e.g., ground or V_{DD}) at the first sensing node 230. Taking for example the current sensing circuit of FIG. 2B, by holding the voltage at the first sensing node near ground potential, the above-mentioned disadvantages of a higher required supply voltage and leakage current can be avoided. Additionally, the present invention enables the use of a larger sensor signal (e.g., 1V) compared to the smaller sensor signal (e.g., 200 mV) used in the prior art systems, and accordingly, a higher degree of accuracy and performance is afforded.

As readily appreciated by those skilled in the art, the described processes may be implemented in hardware, software, firmware or a combination of these implementations as appropriate. For example, the operation of selecting a memory cell may be carried out by word and bitline decoders under the control of an I/O interface unit such as a computer. Further, the operation of applying a reference potential and comparing sensor and reference signals may be performed using a test/measurement device under the control of a computer. Accordingly, the described operations may be implemented as executable instructions stored on a computer readable medium (removable disk, volatile or non-volatile memory, embedded processors, etc.), the stored instruction code operable to program a computer or other such programmable device to carry out the intended functions.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A circuit for sensing current output from a memory cell, the memory cell having an output terminal for supplying memory cell current therefrom, the current sensing circuit comprising:
a sensor element having a first terminal coupled to the output terminal of the memory cell and a second terminal, wherein the first terminal comprises a first sensing node and the second terminal comprises a second sensing node; and
an inverting amplifier having an inverting input coupled to the first sensing node, a reference input for receiving a reference potential, and an output coupled to the second sensing node,
wherein the inverting amplifier is operable to apply substantially the reference potential to the first sensing node and to produce, in response, a sensor signal at the second sensing node, wherein the sensor signal is representative of the cell current applied to the first sensing node.

2. The circuit of claim 1, wherein the reference potential coupled to the reference input of the inverting amplifier is substantially ground potential.

3. The circuit of claim 1, wherein the inverting amplifier comprises an operational amplifier having an inverting input coupled to the first sensing node, a non-inverting input coupled to receive the reference potential, and an output coupled to the second sensing node.

4. The circuit of claim 1, wherein the output terminal of the inverting amplifier is further coupled to receive substantially the memory cell current.

5. The circuit of claim 1, further comprising a comparator operable to receive and compare the sensor signal to a predefined reference signal.

6. The circuit of claim 1, wherein the sensor element comprises a two terminal passive element.

7. The circuit of claim 6, wherein the sensor element comprises a resistor having a resistance value between 50×10³ ohms and 1,000×10³ ohms.

8. The circuit of claim 6, wherein the sensor element comprises a capacitor having a capacitance value between 10×10⁻¹⁵ F and 1000×10⁻¹⁵ F.

9. The circuit of claim 8, further comprising a switch coupled between the capacitor and a predefined potential, wherein the switch is operable to switchably couple the capacitor to the predefined potential.

10. A circuit for sensing current input into a memory cell, the memory cell having an input terminal for receiving memory cell current, the current sensing circuit comprising:
a sensor element having a first terminal coupled to the input terminal of the memory cell and a second terminal, wherein the first terminal comprises a first sensing node and the second terminal comprises a second sensing node; and
an inverting amplifier having an inverting input coupled to the first sensing node, a reference input for receiving a reference potential, and an output coupled to the second sensing node for receiving substantially the memory cell current,
wherein the inverting amplifier is operable to apply substantially the reference potential to the first sensing node, the inverting operable to produce, in response, a sensor signal at the second sensing node, wherein the sensor signal is representative of the memory cell current applied to the first sensing node.

11. The circuit of claim 10, wherein the reference potential coupled to the reference input of the inverting amplifier is substantially a power supply voltage V_{DD} of the memory cell.

12. The circuit of claim 10, wherein the inverting amplifier comprises an operational amplifier having an inverting input coupled to the first sensing node, a non-inverting input coupled to receive the reference potential, and an output coupled to the second sensing node.

13. The circuit of claim 10, further comprising a comparator operable to receive and compare the sensor signal to a predefined reference signal.

14. The circuit of claim 10, wherein the sensor element comprises a two terminal passive element.

15. The circuit of claim 14, wherein the sensor element comprises a resistor having a resistance value between 50×10³ ohms and 1,000×10³ ohms.

16. The circuit of claim 14, wherein the sensor element comprises a capacitor having a capacitance value between 10×10⁻¹⁵ F and 1000×10⁻¹⁵ F.

17. The circuit of claim 16, further comprising a switch coupled between the capacitor and a predefined potential, wherein the switch is operable to switchably couple the capacitor to the predefined potential.

18. A method for sensing current conducted by a memory cell, the method comprising:
supplying memory cell current to, or sinking memory cell current from, a first sensing node, the first sensing node coupled to a first terminal of a sensor element and to a first input port of an inverting amplifier, wherein a second terminal of the sensor element and an output terminal of the inverting amplifier are coupled together and comprise a second sensing node;
applying a reference potential to a reference input of the inverting amplifier, wherein the inverting amplifier is operable to apply substantially the reference potential to the first sensing node and to produce, in response, a sensor signal at the second sensing node; and
detecting the sensor signal at the second sensing node, wherein the sensor signal is representative of the memory cell current supplied to, or sunk from, the first sensing node.

19. The method of claim 18, further comprising comparing the sensor signal to a predefined reference signal.

20. The method of claim 18, wherein applying a reference potential comprises coupling substantially a ground potential to the reference input of the inverting amplifier.

21. The method of claim 18, wherein applying a reference potential comprises coupling substantially a power supply voltage V_{DD} to the reference input of the inverting amplifier.

22. The method of claim 18, wherein the second sensing node is coupled to receive substantially the memory cell current.

23. The method of claim 18, wherein the inverting amplifier comprises an operational amplifier having an inverting input coupled to the first sensing node, a non-inverting input coupled to receive the reference potential, and an output coupled to the second sensing node.

24. The method of claim 18, wherein the sensor element comprises a capacitor, the method further comprising charging the capacitor to a predefined voltage prior to supplying current output from the memory cell to the first sensing node.

25. A computer program product, resident on a computer readable medium, for storing executable instructions for controlling a system to sense current conducted by a memory cell, the computer program product comprising:
instruction code to supply memory cell current to, or sinking memory cell current from, a first sensing node, the first sensing node coupled to a first terminal of a sensor element and to a first input port of an inverting amplifier, wherein a second terminal of the sensor element and an output terminal of the inverting amplifier are coupled together and comprise a second sensing node;
instruction code to apply a reference potential to a reference input of the inverting amplifier, wherein the inverting amplifier is operable to apply substantially the reference potential to the first sensing node and to produce, in response, a sensor signal at the second sensing node; and
instruction code to detect a sensor signal developed at the second sensing node, wherein the sensor signal is representative of the current supplied to, or sunk from, the first sensing node.

26. The computer program product of claim 25, further comprising instruction code to compare the sensor signal to a predefined reference signal.

27. The computer program product of claim 25, wherein the instruction code to apply a reference potential comprises instruction code to couple substantially a ground potential to the reference input of the inverting amplifier.

28. The computer program product of claim 25, wherein the instruction code to apply a reference potential comprises instruction code to couple substantially a power supply voltage V_{DD} to the reference input of the inverting amplifier.

29. The computer program product of claim 25, wherein the second sensing node is coupled to receive substantially the memory cell current.

30. The computer program product of claim 25, wherein the inverting amplifier comprises an operational amplifier having an inverting input coupled to the first sensing node, a non-inverting input coupled to receive the reference potential, and an output coupled to the second sensing node.

31. The computer program product of claim 25, wherein the sensor element comprises a capacitor, the computer program product further comprising instruction code to charge the capacitor to a predefined value prior to supplying current output from the memory cell to the first sensing node.
